(19) United States
(12) Patent Application Publication
(10) Pub. No.: US 2007/0138574 A1
(43) Pub. Date: Jun. 21, 2007

(54) SEMICONDUCTOR DEVICE AND MANUFACTURING METHOD THEREFOR

(75) Inventors: Katsumi EIKYU, Tokyo (JP); Tomohiro Yamashita, Tokyo (JP); Katsuyuki Horita, Tokyo (JP); Takashi Hayashi, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Chiyoda-ku (JP)

(21) Appl. No.: 11/563,500

(22) Filed: Nov. 27, 2006

(30) Foreign Application Priority Data
Dec. 20, 2005 (JP) 2005-365867

(51) Int. Cl. H01L 29/76

(52) U.S. Cl. 257/384

(57) ABSTRACT

The top ends of polysilicon gate electrodes with different gate lengths are formed so as to be equally high and lower than the top end of the side wall. A metal film is formed so as to cover the polysilicon gate electrodes, followed by silicidation by thermal treatment. Since the top ends of the polysilicon gate electrodes are formed lower than the top end of the side wall, a silicon side reaction is not accelerated even in the case of a fine gate length, and proceeds in a one-dimensional manner. As a result, full-silicide gate electrodes having a uniform metal composition ratio can be stably formed even using the polysilicon gates with different gate lengths.

### BACKGROUND OF THE INVENTION

1. Field of the Invention

The present invention relates to a semiconductor device, and a manufacturing method therefor. In particular, the present invention relates to a semiconductor device including a MISFET which includes a fully silicided gate electrode, and a manufacturing method therefor.

2. Description of the Background Art

In Japanese Patent Application Laid-Open No. 11-284179 (1999), there is provided a so-called full silicide (FUSI) technique as a technique capable of relatively easily preparing a metal gate. In this technique, polysilicon is formed as a gate electrode up to a source/drain region in the same manner as in a normal MISFET formation flow, and a metal such as Ni is then deposited on the polysilicon. Subsequently, the metal is reacted with Si by annealing to fully silicide the polysilicon for formation of a full-silicide gate electrode.

At this time, NiSix is also formed on the source/drain region simultaneously on the gate electrode. Since a gate electrode typically has a height substantially larger than the thickness of NiSix required for the source/drain region, NiSix formed on the source/drain region simultaneously with the full silicidation of the gate electrode has an excessively large thickness, which causes a device characteristic problem.

In order to solve this problem, the following process has been contrived. Silicide is formed on the source/drain region while a cap film is deposited on the gate electrode, and thereafter, an interlayer insulation film is formed. The top of the cap film is exposed and then etched for removal by CMP, to fully silicide only the gate electrode (refer to Japanese Patent Application Laid-Open No. 2004-221226).

However, in the conventional FUSI gate formation process by means of NiSix, when a MISFET with a large gate length and a MISFET with a fine gate length are simultaneously formed, NiSix formed in the MISFET with a fine gate length has a higher Ni composition ratio than that of NiSix formed in the MISFET with a large gate length.

Further, in some cases, cubical expansion becomes significant, resulting in protrusion of NiSix to the upper portion of the gate electrode or penetration of NiSix through the insulating film to reach a silicon substrate.

Moreover, it is known that, since a work function changes with a change in composition of NiSix even the cubic expansion is not significant, a threshold voltage Vth of the transistor changes discontinuously with respect to the gate length (refer to J. A. Kittl et al., in Symp. on VLSI Tech., Dig., 2005, p72)

J. A. Kittl et al. proposes two-stage annealing in formation of NiSix to control the NiSix composition of a gate with a length as fine as the order of 30 nm, thereby solving the discontinuity of Vth.

However, in the invention of J. A. Kittl et al, since the NiSix composition is controlled by temperature control in annealing, it is difficult to control the NiSix composition with precision and ease. Further, the foregoing problem of cubical expansion cannot be solved by the invention of J. A Kittl et al.

Moreover, since compositions of gate electrodes in the P-type MISFET and the N-type MISFET are not separately controllable by temperature control in annealing, it is difficult to form a so-called dual work function metal gate CMOS structure, which has gate electrodes with different work functions.

### SUMMARY OF THE INVENTION

Therefore, it is an object of the present invention to provide a semiconductor device and a manufacturing method therefor, the semiconductor device including full-silicide gate electrodes with a uniform metal composition ratio even with different gate lengths, and being capable of controlling the metal composition with ease.

In a first aspect of a semiconductor device according to the present invention, the semiconductor device includes at least one MISFET which has: a full-silicide gate electrode, formed on a semiconductor substrate via a gate insulating film, and fully silicided; and side walls each formed on the side surfaces of the gate insulating film and the full-silicide gate electrode, wherein the top end of the full-silicide gate electrode is lower than the top end of the side wall.

According to the above semiconductor device, it is possible to apply a manufacturing method of forming the top end of the polysilicon gate electrode so as to be lower than the top end of the side wall for silicidation, thereby to form a full-silicide gate electrode. With the top end of the polysilicon gate electrode lower than the top end of the side wall, a silicide reaction can be promoted in a one-dimensional manner regardless of the gate length.

It is therefore possible to obtain a semiconductor device which includes full-silicide gate electrodes having a uniform metal composition ratio even with different gate lengths.

Further, since controlling the heights of the polysilicon gate electrodes allows controlling a volume of silicon with respect to the metal supplied in the silicide reaction, the metal composition of the full-silicide gate electrode can be controlled with ease.

In a second aspect of a semiconductor device according to the present invention, the semiconductor device includes at least one MISFET which has: a full-silicide gate electrode, formed on a semiconductor substrate via a gate insulating film, and fully silicided; and side walls each formed on the side surface of the full-silicide gate electrode, wherein at least one MISFET has: a first MISFET in which the top end of the full-silicide gate electrode is formed so as to be lower than the top end of the side wall; and a second MISFET in which the top end of the full-silicide gate electrode is formed so as to be higher than the top end of the side wall.

According to the semiconductor device mentioned above, it is possible to apply a manufacturing method of forming the top end of the polysilicon gate electrode so as to be lower than the top end of the side wall in the first MISFET while forming the top end of the polysilicon gate so as to be higher than the top end of the side wall in the second MISFET, for silicidation.

The polysilicon gate in the first MISFET is subjected to one-dimensional silicidation, and the polysilicon gate electrode in the second MISFET is subjected to two-dimensional or three-dimensional slicidation, thereby to accelerate the silicide reaction.

Therefore, the full-silicide gate electrode in the first MISFET has a metal composition smaller than that of the full-silicide gate electrode in the second MISFET.

As a result, it is possible to facilitate realization of a semiconductor device in which the first MISFET and the second MISFET have the full-silicide gate electrodes with different work functions.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A and 1B are sectional views showing a configuration of a semiconductor device according to a first embodiment;

FIGS. 2A and 2B are sectional views showing a manufacturing process of the semiconductor device according to the first embodiment;

FIGS. 3A and 3B are sectional views showing a manufacturing process of a conventional semiconductor device.

FIG. 4 is a sectional view showing a configuration of a semiconductor device according to a second embodiment;

FIG. 5 is a sectional view showing a manufacturing process of the semiconductor device according the second embodiment;

FIG. 6 is a sectional view showing a manufacturing process of the semiconductor device according to the second embodiment;

FIG. 7 is a sectional view showing a manufacturing process of the semiconductor device according to the second embodiment;

FIG. 8 is a sectional view showing a manufacturing process of the semiconductor device according to the second embodiment;

FIG. 9 is a sectional view showing a manufacturing process of the semiconductor device according to the second embodiment;

FIG. 10 is a sectional view showing a manufacturing process of the semiconductor device according to the second embodiment;

FIG. 11 is a sectional view showing a manufacturing process of the semiconductor device according to the second embodiment;

FIG. 12 is a sectional view showing a manufacturing process of the semiconductor device according to the second embodiment;

FIGS. 13A and 13B are sectional views showing a manufacturing process of a semiconductor device according a third embodiment;

FIGS. 14A and 14B are sectional views showing a manufacturing process of the semiconductor device according the third embodiment;

FIG. 15 is a sectional view showing a configuration of the semiconductor device according a fourth embodiment;

FIG. 16 is a sectional view showing a manufacturing process of the semiconductor device according to the fourth embodiment;

FIG. 17 is a sectional view showing a manufacturing process of the semiconductor device according to the fourth embodiment;

FIG. 18 is a sectional view showing a manufacturing process of the semiconductor device according to the fourth embodiment;

### DESCRIPTION OF THE PREFERRED EMBODIMENTS

### First Embodiment

### A. Configuration

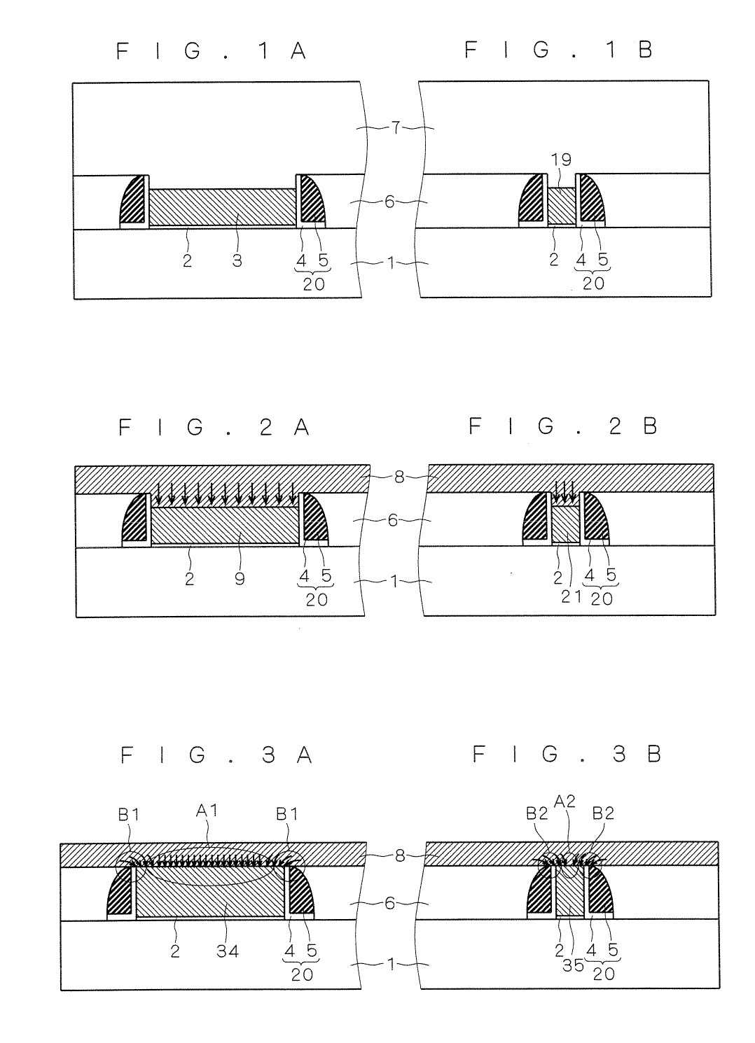

FIGS. 1A and 1B are sectional views showing a configuration of a semiconductor device according to a first embodiment. As shown in FIG. 1A, a MISFET with a large gate length and a MISFET (FIG. 1B) with a fine gate length are formed in the semiconductor device according to the first embodiment.

An interlayer insulating film 6 is formed on a semiconductor substrate 1. Full silicide gate electrodes (also referred to as metal gate electrodes) 3, 19 which are fully silicided are formed inside the interlayer insulating film 6 on the semiconductor substrate 1 via a gate insulating film 2.

The full silicide gate electrode 3 is formed on the gate insulating film 2 in the MISFET with a large gate length. Further, the full silicide gate electrode 19 is formed on the gate insulating film 2 in the MISFET with a fine gate length.

Here, each of the full silicide gate electrodes 3, 19 is a gate electrode fully silicided from its upper portion to its face (bottom) bonded to the gate insulating film 2.

A side wall 20 composed of a first side wall 4 and a second side wall 5 is formed on each side surface of the gate insulating film 2 and the full silicide gate electrodes 3, 19. An interlayer insulating film 7 is formed on the interlayer insulating film 6 so as to cover the full silicide gate electrodes 3, 19.

Here, the top ends of the full silicide gate electrodes 3, 19 are formed so as to be lower than the top end of the side wall 20. Further, the full silicide gate electrode 3 and the full-silicide gate electrode 19 are formed so as to have the same height.

It is to be noted that, while a source/drain region and the like are formed on the semiconductor substrate 1, details thereof are omitted in FIGS. 1A and 1B since the source/drain region has a weak relation with the characteristic of the first embodiment.

### B. Manufacturing Method

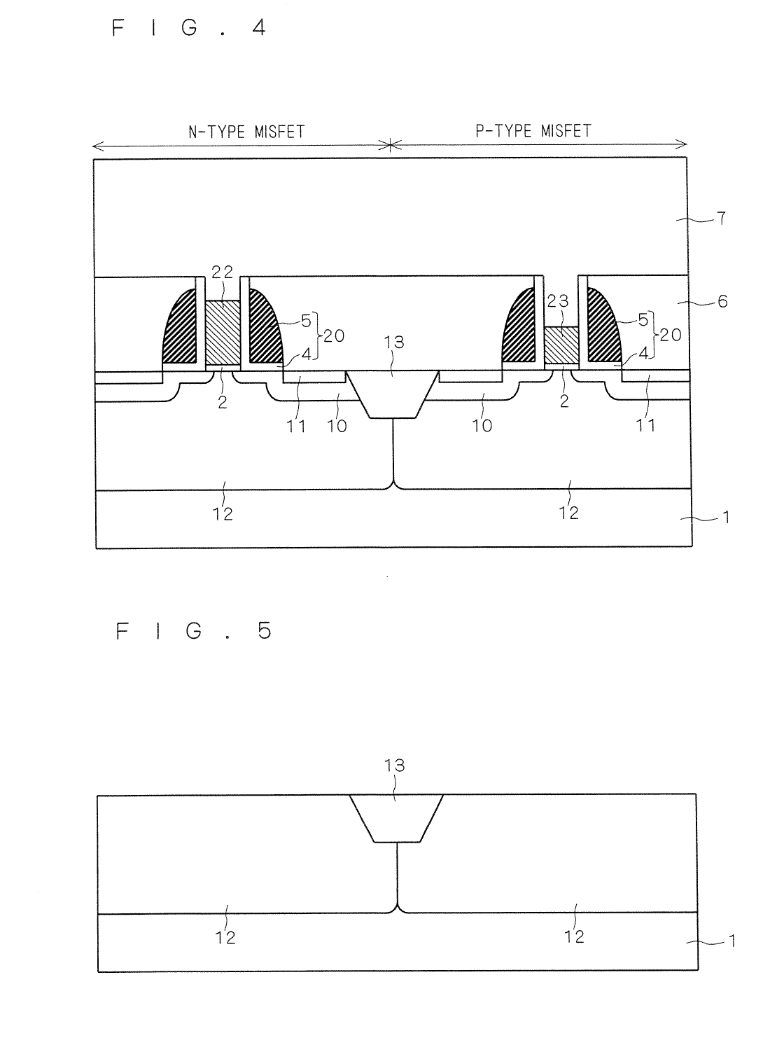

FIGS. 2A and 2B are sectional views showing a manufacturing process of a semiconductor device according to the first embodiment. FIGS. 2A and 2B are views showing a manufacturing process of fully siliciding the polysilicon gate electrodes 9, 21 to form the full silicide gate electrodes 3, 19, out of manufacturing processes of the semiconductor device.

First, the semiconductor substrate 1 is prepared which includes on its main surface a structure composed of the polysilicon gate electrodes 9, 21 formed via the gate insulating film 2, the gate insulating film 2, and the side walls 20 each formed on the side surfaces of the gate insulating film 2 and the polysilicon gate electrodes 9, 21.

The top ends of the polysilicon gate electrodes 9, 21 are adjusted by etching so as to be lower than the top end of the side wall 20. Here, the polysilicon gate electrode 21 and the polysilicon gate electrode 9 are formed so as to have the same height.

Next, a metal film 8 such as Ni is formed so as to cover the polysilicon gate electrodes 9, 21.

Subsequently, as shown in FIGS. 2A and 2B, thermal treatment is performed to make a silicide reaction between the metal film 8 and the polysilicon gate electrodes 9, 21. The polysilicon gate electrodes 9, 21 are fully silicided to the bottoms thereof, to form the full silicide gate electrodes 3, 19.

It is to be noted that the arrows shown in FIGS. 2A and 2B indicate the flow of metal atoms supplied in the silicide reaction process.

After removal of the non-reactive metal film 8, an interlayer insulating film 7 is deposited all over the surface of the semiconductor substrate 1 to complete the semiconductor device shown in FIGS. 1A and 1B.

### C. Effect

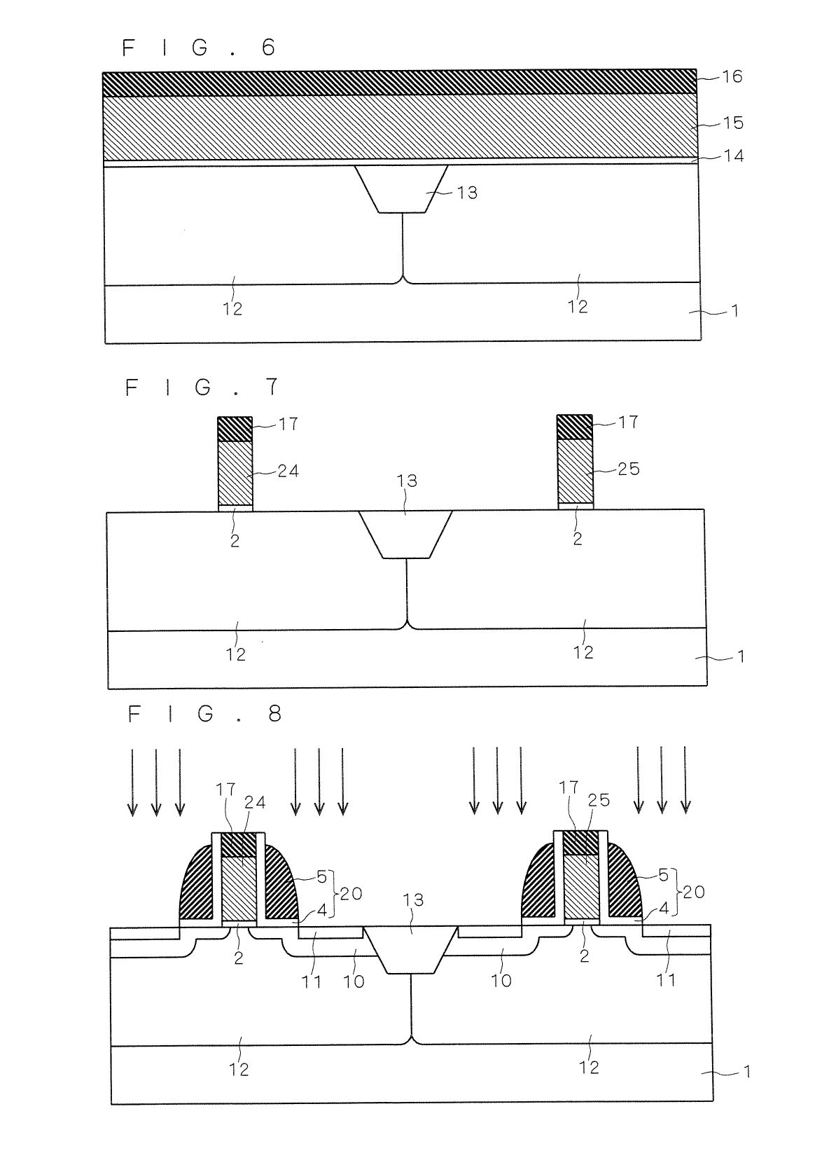

FIGS. 3A and 3B show sectional views showing a manufacturing process of a conventional semiconductor device. FIGS. 3A and 3B show a process of siliciding polysilicon gate electrodes 34, 35. Further, the arrows shown in FIGS. 3A and 3B, similar to FIGS. 2A and 2B, indicate the flow of the metal atoms supplied in the silicide reaction process.

As shown in FIGS. 3A and 3B, in the method for manufacturing the conventional semiconductor device, the top ends of the polysilicon gate electrodes 34, 35 are formed so as to have the same heights as that of the top end of the side wall 20.

As shown in FIGS. 3A and 3B, when the polysilicon gate electrode 34 with a large gate length is silicided, the ratio of the metal atoms supplied from the both side portions B1 of the polysilicon gate electrode 34 is small as compared with the metal atoms supplied from the front portion A1 of the polysilicon gate electrode 34. For this reason, the silicide reaction proceeds in an almost one-dimensional manner in the polysilicon gate electrode 34 with a large gate length.

As opposed to this, when the polysilicon gate electrode 35 with a fine gate length is silicided, the ratio of the metal atoms supplied from the both side portions B2 of the polysilicon gate electrode 35 is large as compared with the metal atoms supplied from the front portion A2 of the polysilicon gate electrode 35.

Therefore, the silicide reaction proceeds in a two-dimensional manner in the polysilicon gate electrode 35 with a fine gate length. Further, when the gate electrode 35 also has a fine gate width, the silicide reaction proceeds in a three-dimensional manner.

Consequently, the silicide reaction is accelerated in the polysilicon gate electrode 35 with a fine gate length as compared with the polysilicon gate electrode 34, to facilitate formation of a fully silicide gate electrode having a large metal composition ratio. Further, the increase in metal composition ratio of the full-silicide gate electrode might cause penetration of the full-silicide gate electrode through the gate insulating film 2 due to cubical expansion thereof.

In the method for manufacturing the semiconductor device according to the first embodiment, the top end of the polysilicon gate electrode 21 is formed so as to be lower than the top end of the side wall 20. For this reason, since a supply channel for a metal (e.g. Ni) from both sides can be blocked off even in the case of the polysilicon gate electrode 21 with a fine gate length, the silicide reaction surface can be made one-dimensional. Therefore, even in the case of the fine gate length (or gate width), the metal atoms are supplied in a two-dimensional or three-dimensional manner, thereby to suppress the accelerated progress of silicidation.

Since the suicide reaction can be made one-dimensional irrespective of the gate length (or gate width), equalizing the heights of the top ends of the polysilicon gate electrodes 9, 21 allows stable formation of the full silicide gate electrodes 3, 19 which have the same composition ratio.

Further, since even the metal composition ratio of the full-silicide gate electrode 19 with a fine gate length does not increase as compared with that of the full-silicide gate electrode with a large gate length, it is possible to suppress the defect due to the cubical expansion.

In the semiconductor device according to the first embodiment, since the top ends of the full silicide gate electrodes 3, 19 are lower than the top end of the side wall 20, the full silicide gate electrodes 3, 19 having a uniform metal composition ratio can be formed with ease.

### Second Embodiment

A semiconductor device according to a second embodiment is one obtained by applying the first embodiment to a CMOS structure.

### A. Configuration

FIG. 4 is a sectional view showing a configuration of the semiconductor device according to the second embodiment. The semiconductor device according to the second embodiment includes a COMS configuration in which an N-type MISFET (nFET) and a P-type MISFET (pFET) are formed.

As shown in FIG. 4, the nFET and the pFET are separated from each other by an STI (shallow trench isolation) 13. Well regions 12 are formed on the upper layer portion of the semiconductor substrate 1. A source/drain region 10 is formed on the upper layer portion of the well regions 12.

The interlayer insulating film 6 is formed on the semiconductor substrate 1. In the nFET formation region, a full-silicide gate electrode 22 is formed inside the interlayer insulating film 6 on the semiconductor substrate 1 via the gate insulating film 2. Further, in the pFET formation region, the full silicide gate electrode 23 is formed inside the interlayer insulating film 6 on the semiconductor substrate 1 via the gate insulating film 2.

On each of side surfaces of the gate insulating film 2 and the full silicide gate electrodes 22, 23, the side wall 20 is formed which is composed of the first side wall 4 and the second side wall 5.

Here, the full silicide gate electrodes 22, 23 are gate electrodes fully silicided to the bottoms thereof.

The top ends of the full silicide gate electrodes 22, 23 are formed so as to be lower than the top end of the side wall 20. Further, the top end of the full silicide gate electrode 23 in the P-type MISFET is formed so as to be lower than the top end of the full silicide gate electrode 22 in the N-type MISFET.

Here, the full suicide gate electrodes 22, 23 are obtained by siliciding Ni, Co, Ti or the like, and include a number of phases with different composition ratios or the like.

In the CMOS structure according to the first embodiment, the full silicide gate electrode 22 in the nFET and the full silicide gate electrode 23 in the pFET have different metal-silicide composition ratios. The full silicide gate electrode 23 has a metal-rich composition as compared with the full silicide gate electrode 22. For example, NiSi is used for the full silicide gate electrode 22, and Ni₃Si is used for the full silicide gate electrode 23.

Further, the full silicide gate electrodes 22, 23 in an identical conductor type MISFETs have the uniform height.

Further, the interlayer insulating film 7 is formed on the interlayer insulating film 6 so as to cover the full silicide gate electrodes 22, 23.

### B. Manufacturing Method

Next, a method for manufacturing the semiconductor device according to the second embodiment is described with reference to FIGS. 5 to 12. FIGS. 5 to 12 are sectional views showing manufacturing processes of the semiconductor device according to the second embodiment.

First, in the process shown in FIG. 5, the STI 13 and the well regions 12 are formed on the semiconductor substrate 1.

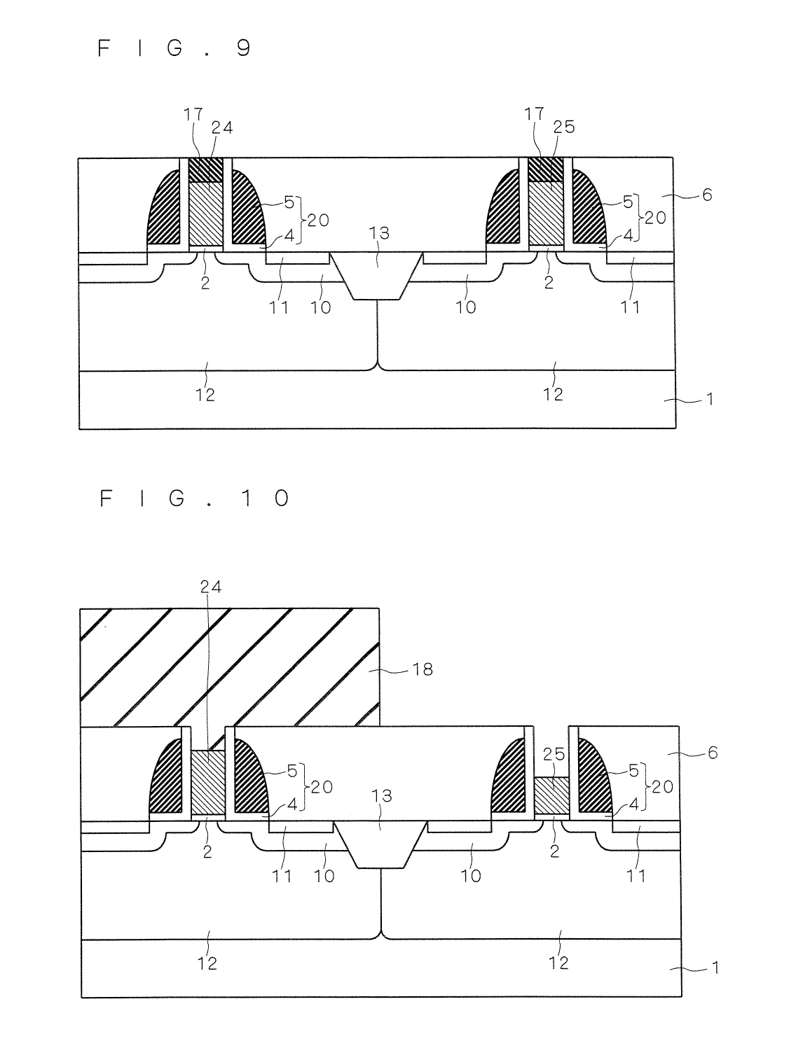

Next, in the process shown in FIG. 6, an insulating film 14 to be the gate insulating film 2 and a polysilicon film 15 are deposited in this order in the same manner as in a typical MISFET formation process. Here, a material for the insulating film 14 is a silicon oxynitride film, a high-k insulating film, a film stack of those, or the like.

Subsequently, an insulating film 16 is deposited on the polysilicon film 15. A material for the insulating film 16 is, for example, an oxide film, a silicon nitride film, the silicon oxynitride film, or the like.

Next, in the process shown in FIG. 7, the insulating film 14, the polysilicon film 15 and the insulating film 16 are etched by dry etching, to form the gate insulating film 2, polysilicon gate electrodes 24, 25, and the cap film 17.

Next, in the process shown in FIG. 8, an extension layer is formed by ion implantation in the same manner as in the typical MISFET formation process. Here, an offset spacer may be formed prior to ion plantation. Further, a pocket layer (also called a hello layer) may be formed by ion plantation.

Subsequently, an insulating film is deposited on the semiconductor substrate 1 so as to cover the polysilicon gate electrodes, followed by dry etching, to form the side walls 20 each composed of the first side wall 4 and the second side wall 5. The side wall 20 is formed on each of the side surfaces of the gate insulating film 2, the polysilicon gate electrodes 23, 24 and the cap film 17.

Here, the side wall 20 typically has a double-layer or triple-layer laminated structure composed of an oxide film and a nitride film. FIG. 8 shows an example of the double-layer structure.

Subsequently, the source/drain region 10 is formed by ion implantation, and impurities are then activated by thermal treatment. Subsequently, a metal film is deposited, to form a silicide layer 11 on the source/drain region 10. A material for the metal film is Ni, Co, Ti or the like. At this time, since the cap film 17 is inserted onto the polysilicon gate electrodes 24, 25, silicide is not formed on the polysilicon gate electrodes 24, 25.

By the above-mentioned process, the semiconductor substrate 1 is prepared which includes on its main surface a structure having the polysilicon gate electrode 24, 25 formed via the gate insulating film 2, the cap films 17 formed on the polysilicon gate electrodes 24, 25, the gate insulating films 2, and the side walls 20 each formed on the side walls of the cap film 17 and the polysilicon gate electrodes 24, 25.

Here, while FIG. 8 shows structures with the same gate length, the structure in the P-type MISFET and the structure in the N-type MISFET may have different gate lengths. Further, the structures in the P-type MISFET may have different gate lengths, and the structures in the N-type MISFET may have different gate lengths. Namely, the semiconductor substrate 1 including a plurality of structures with different gate lengths may be prepared.

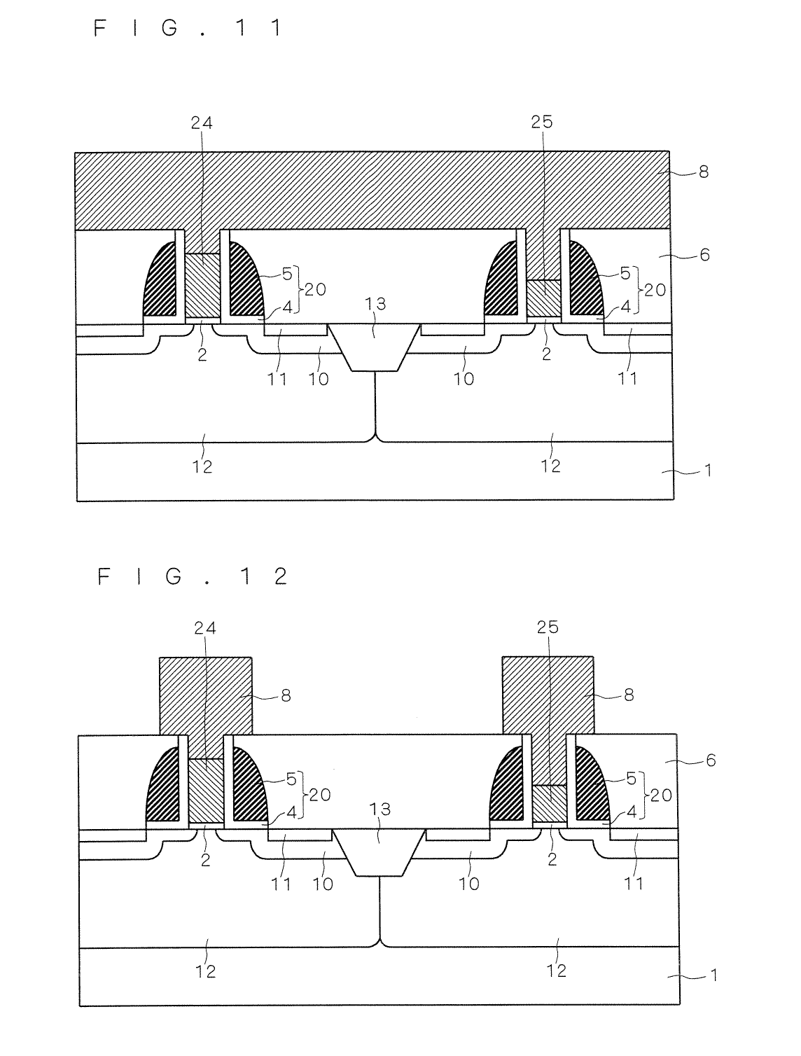

Next, in the processes shown in FIGS. 9 and 10, the heights of the top ends of the polysilicon gate electrodes 24, 25 are adjusted by etching.

First, in the process of FIG. 9, the interlayer insulating film 6 is deposited on the semiconductor substrate 1 and then ground by CMP, to expose the surface of the cap film 17.

Next, in the process shown in FIG. 10, after removal of the cap film 17 by wet etching or the like, a resist 18 is formed so as to cover the nFET formation region. Using the resist 18 as a mask, the polysilicon gate electrode 25 in the pFET is etched. The height of the polysilicon gate electrode 25 is adjusted by etching to adjust a volumetric ratio of the polysilicon gate electrode 25 to the later-described metal film 8.

Similarly on the nFET side, after formation of the resist on the pFET side, a volumetric ratio of the polysilicon gate electrode 24 to the metal film 8 is adjusted by etching. This process is performed on either/both the nFET or/and the pFET according to the need.

Here, in order to make the silicide reaction surface as one-dimensional as possible, the distance between each of the top ends of the polysilicon gate electrodes 24, 25 and the top end of the side wall 20 is preferably 30 nm or longer.

Further, the distance between each of the top ends of the polysilicon gate electrodes 24, 25 and the top end of the side wall 20 can be adjusted by the thickness of the cap film 17 and etching of the polysilicon gate electrodes 24, 25 after removal of the cap film 17.

Next, in the process shown in FIG. 11, the metal film 8 such as Ni is deposited on the interlayer insulating film 6 so as to cover the polysilicon gate electrodes 24, 25.

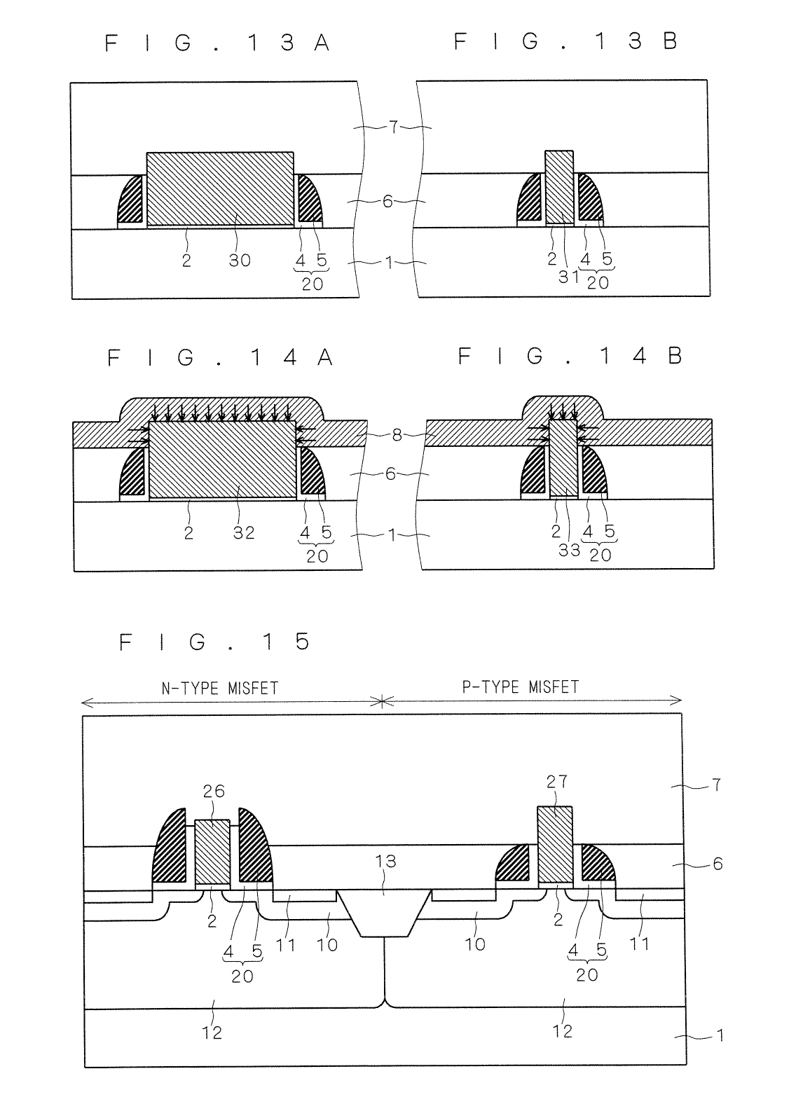

Here, as shown in FIG. 12, after the process of FIG. 11, the metal film 8 in the region other than the upper portions of the polysilicon gate electrodes 24, 25 may be removed by mask-etching. This can suppress the progress of the silicide reactions from the side faces of the polysilicon gate electrodes 24, 25.

Subsequently, the polysilicon gate electrodes 24, 25 are fully silicided by thermal treatment to form the full silicide gate electrodes 22, 23.

Next, after removal of the non-reactive metal film 8, the interlayer insulating film 7 is deposited all over the surface of the semiconductor substrate 1 so that a semiconductor device shown in FIG. 4 can be obtained.

### C. Effect

A phenomenon in which the work function changes depending upon the gate length is attributed to that the flow of metal atoms supplied in the silicide reaction process become two-dimensional or three-dimensional at the gate end and the silicon reaction is accelerated in the case of the fine length.

However, by formation of the top ends of the polysilicon gate electrodes 24, 25 so as to be lower than the top end of the side wall 20 in the silicide reaction, it is possible to block the supply of the metal from the side faces, so as to maintain almost a one-dimensional silicide reaction even at the polysilicon gate electrodes 24, 25 with fine gate lengths.

The method for manufacturing the semiconductor device according to the second embodiment includes a step of adjusting the height of the top ends of the polysilicon gate electrodes 24, 25 by etching.

Therefore, by adjusting the top ends of the polysilicon gate electrodes 24, 25 so as to be lower than the top end of the side wall 20, it is possible to bring about the one-dimensional silicide reaction without depending upon the gate length.

Even in a semiconductor device including the P-type MISFETs with different gate lengths, it is possible to form the full silicide gate electrodes 22 having the same composition ratio by making the height of each of the polysilicon gate electrodes 24 uniform among the plurality of P-type MISFETs.

Further, similarly in a semiconductor device including the N-type MISFETs with different gate lengths, it is possible to form the full silicide gate electrodes 23 having the same composition ratio by making the height of each of the polysilicon gate electrodes 25 uniform among the plurality of N-type MISFETs.

Further, by adjusting the heights of the top ends of the polysilicon gate electrodes 24, 25, the metal composition ratios of the full silicide gate electrodes 22, 23 can be adjusted with ease.

The manufacturing method of the semiconductor device according to the second embodiment includes a step of adjusting the top end of the polysilicon gate electrode 25 in the P-type MISFET so as to be lower than the top end of the polysilicon gate electrode 24 in the N-type MISFET.

Since the amount of silicon in the polysilicon gate electrode 25 becomes smaller than that of the polysilicon gate electrode 24, the full silicide gate electrode 23 has a larger metal composition ratio than that of the full suicide gate electrode 22 after the silicide reaction.

As a result, the work function of the full silicide gate electrode 23 in the pFET can be made larger than the work function of the full silicide gate electrode 22 in the nFET, and it is thereby possible to form the full silicide gate electrodes 22, 23 with optimum, different work functions.

By application of the manufacturing method described above, the semiconductor device according to the second embodiment can realize the so-called dual work function metal gate CMOS structure, and also realize a full-silicide gate electrode having a stable work function without depending upon a gate length and gate width.

Further, it is possible to facilitate formation of a plurality of identical conductive type MISFETs which include the full silicide gate electrodes 22, 23 having a uniform metal composition ratio.

### Third Embodiment

### A. Configuration

FIGS. 13A and 13B are sectional views showing a configuration of a semiconductor device according to a third embodiment. As shown in FIG. 13A, a MISFET with a large gate length and a MISFET (FIG. 13B) with a fine gate length are formed in the semiconductor device according to the third embodiment.

The interlayer insulating film 6 is formed on the semiconductor substrate 1. Full silicide gate electrodes (also referred to as metal gate electrodes) 30, 31 which are fully silicided are formed inside the interlayer insulating film 6 on the semiconductor substrate 1 via the gate insulating film 2.

The full silicide gate electrode 30 is formed on the gate insulating film 2 in the MISFET with a large gate length. Further, the full silicide gate electrode 31 is formed on the gate insulating film 2 in the MISFET with a fine gate length.

Here, each of the full silicide gate electrodes 30, 31 is a gate electrode fully silicided from its upper portion to its face (bottom) bonded to the gate insulating film 2.

The side wall 20 composed of the first side wall 4 and the second side wall 5 is formed on each side surface of the gate insulating film 2 and the full silicide gate electrodes 30, 31. The interlayer insulating film 7 is formed on the interlayer insulating film 6 so as to cover the full silicide gate electrodes 30, 31.

Here, the top ends of the full silicide gate electrodes 30, 31 are formed so as to be higher than the top end of the side wall 20. Further, the full silicide gate electrode 30 and the full-silicide gate electrode 31 are formed so as to have the same height.

It is to be noted that, while a source/drain region and the like are formed on the semiconductor substrate 1, details thereof are omitted in FIGS. 13A and 13B since the source/drain region has a weak relation with the characteristic of the third embodiment.

### B. Manufacturing Method

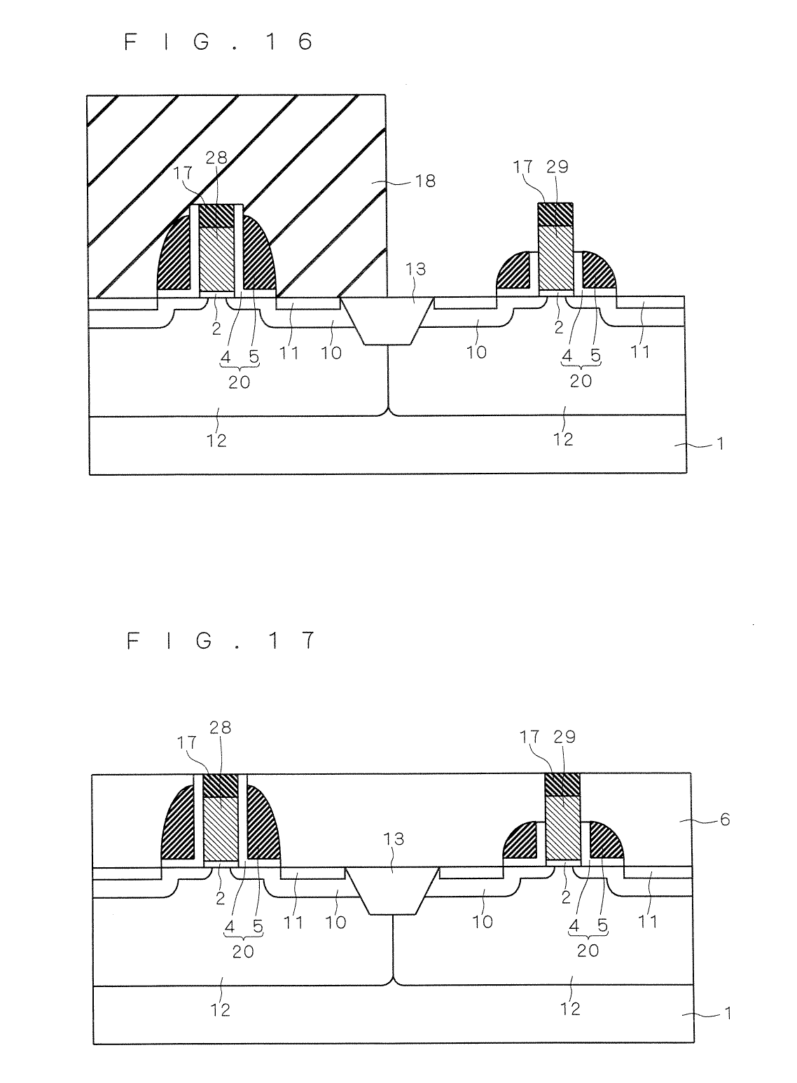

FIGS. 14A and 14B are sectional views showing a manufacturing process of a semiconductor device according to the third embodiment. FIGS. 14A and 14B are views showing a manufacturing process of fully siliciding the polysilicon gate electrodes 32, 33 to form the full silicide gate electrodes 30, 31, out of manufacturing processes of the semiconductor device.

First, the semiconductor substrate 1 is prepared which includes on its main surface a structure composed of the polysilicon gate electrodes 32, 33 formed via the gate insulating film 2, the gate insulating film 2, and the side walls 20 each formed on the side surfaces of the gate insulating film 2 and the polysilicon gate electrodes 32, 33.

The top ends of the polysilicon gate electrodes 32, 33 are adjusted so as to be higher than the top end of the side wall 20. Here, the polysilicon gate electrode 33 and the polysilicon gate electrode 32 are formed so as to have the same height.

Next, the metal film 8 such as Ni is formed so as to cover the polysilicon gate electrodes 32, 33.

Subsequently, as shown in FIGS. 14A and 14B, thermal treatment is performed to make a silicide reaction between the metal film 8 and the polysilicon gate electrodes 32, 33. The polysilicon gate electrodes 32, 33 are fully silicided to the bottoms thereof, to form the full silicide gate electrodes 30, 31.

It is to be noted that the arrows shown in FIGS. 14A and 14B indicate the flow of metal atoms supplied in the silicide reaction process.

After removal of the non-reactive metal film 8, the interlayer insulating film 7 is deposited all over the surface of the semiconductor substrate 1 to complete the semiconductor device shown in FIGS. 13A and 13B.

### C. Effect

In the semiconductor device according to the third embodiment, the top ends of the polysilicon gate electrodes 32, 33 are formed so as to be higher than the top end of the side wall 20. Configuring the silicide reaction surface in the two-dimensional or three-dimensional manner leads to acceleration of the flow of the metal atoms so that the full silicide gate electrodes 30, 31 having a metal-rich composition can be formed with ease.

For this reason, even in the case of a polysilicon gate electrode with a large gate length and a large volume, such as the polysilicon gate electrode 32, the top end of the polysilicon gate electrode 32 can be made high so that the full silicide gate electrode 30 with a metal-rich composition can be formed with ease.

Here, the amount of metal atoms that can be taken into the polysilicon gate electrodes 32, 33 per unit volume has been determined.

Accordingly, even when the height of the top end of the full-silicide gate electrode 33 is equalized to that of the top end of the full-silicide gate electrode 32, the metal composition ratio of the full-silicide gate electrode 31 does not exceed the metal composition ratio of the full-silicide gate electrode 30, and those metal composition ratios can be equalized.

Accordingly, in the semiconductor device according to the third embodiment, the full silicide gate electrodes 30, 31 having a uniform metal-rich composition ratio can be stably formed with ease irrespective of the gate length (or gate width).

### Fourth Embodiment

A semiconductor device according to a fourth embodiment is one obtained by applying the semiconductor device according to any one of the first to third embodiments to a CMOS structure.

### A. Configuration

FIG. 15 is a sectional view showing a configuration of the semiconductor device according to the fourth embodiment The semiconductor device according to the fourth embodiment includes a COMS configuration in which an N-type MISFET (nFET) and a P-type MISFET (pFET) are formed.

As shown in FIG. 15, the nFET and the pFET are separated from each other by the STI 13. The well regions 12 are formed on the upper layer portion of the semiconductor substrate 1. The source/drain region 10 is formed on the upper layer portion of the well regions 12.

The interlayer insulating film 6 is formed on the semiconductor substrate 1. In the nFET formation region, a full-silicide gate electrode 26 is formed inside the interlayer insulating film 6 on the semiconductor substrate 1 via the gate insulating film 2. Further, in the pFET formation region, the full silicide gate electrode 27 is formed inside the interlayer insulating film 6 on the semiconductor substrate 1 via the gate insulating film 2.

On each of side surfaces of the gate insulating film 2 and the full silicide gate electrodes 26, 27, the side wall 20 is formed which is composed of the first side wall 4 and the second side wall 5.

Here, the full silicide gate electrodes 26, 27 are gate electrodes fully silicided to the bottoms thereof.

The top end of the full silicide gate electrode 26 is formed so as to be lower than the top end of the side wall 20, and the top end of the full silicide gate electrode 27 in the P-type MISFET is formed so as to be higher than the top end of the side wall 20.

Namely, in the fourth embodiment, the N-type MISFET is understood as the first MISFET with its top end formed so as to be lower than the top end of the side wall 20. Further, the P-type MISFET is understood as the second MISFET with its top end formed so as to be higher than the top end of the side wall 20.

Here, the full silicide gate electrodes 26, 27 are obtained by siliciding Ni, Co, Ti or the like, and include a number of phases with different composition ratios or the like.

In the CMOS structure according to the fourth embodiment, the full silicide gate electrode 26 in the nFET and the full silicide gate electrode 27 in the pFET have different metal-silicide composition ratios. The full silicide gate electrode 27 has a metal-rich composition as compared with the full silicide gate electrode 26. For example, NiSi is formed in the full silicide gate electrode 26, and Ni₃Si is formed in the full silicide gate electrode 27.

Further, the interlayer insulating film 7 is formed on the interlayer insulating film 6 so as to cover the full silicide gate electrodes 26, 27.

### B. Manufacturing Method

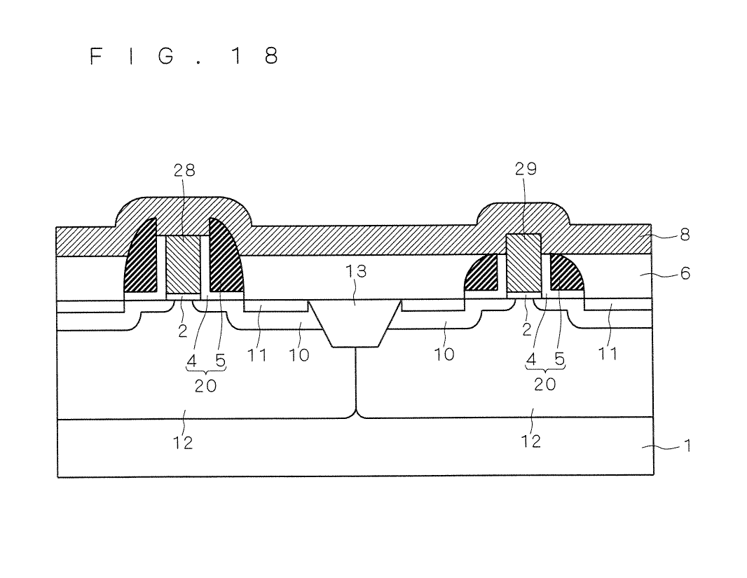

Next, a method for manufacturing the semiconductor device according to the fourth embodiment is described with reference to FIGS. 16 to 18. FIGS. 16 to 18 are sectional views showing manufacturing processes of the semiconductor device according to the fourth embodiment.

Since the same manufacturing processes are performed as those of the second embodiment until the process shown in FIG. 8, detailed descriptions of these processes are omitted.

After the same configuration as in FIG. 8 is obtained, in the process shown in FIG. 16, the side wall 20 is etched such that the polysilicon gate electrode 29 is higher than the side wall 20.

Specifically, first, the resist 18 is formed so as to cover the N-type MISFET formation region. Next, the side wall 20 of the P-type MISFET is etched back by anisotropic etching, to partially expose the side face of the polysilicon gate electrode 29.

Thereby, the top end of the polysilicon gate electrode 29 is formed so as to be higher than the top end of the side wall 20.

Here, in the fourth embodiment, the distance between the top end of the polysilicon gate electrode 28 and the side wall 20 can be adjusted by means of the thickness of the cap film 17 on the polysilicon gate electrode 28 side with each side face thereof not exposed. Further, the distance between the top end of the polysilicon gate electrode 29 and the side wall 20 can be adjusted by means of the amount of etch-back of the side wall 20 on the polysilicon gate electrode 29 side with each side face thereof exposed.

Next, in the process shown in FIG. 17, after removal of the resist 18, the interlayer insulating film 6 is deposited and then ground by CMP, to expose the surface of the cap film 17.

Next, in the process shown in FIG. 18, the cap film 17 is removed by wet-etching or the like. Subsequently, the interlayer insulating film 6 is etched back to the top end of the side wall 20 on the P-type MISFET side, whereafter the metal film 8 such as Ni is deposited on the interlayer insulating film 6.

Here, as shown in FIG. 12 of the first embodiment, the metal film 8 in the region other than the upper portions of the polysilicon gate electrodes 28, 29 may be removed by mask-etching. This can suppress the progress of the silicide reaction from the side faces of the polysilicon gate electrodes 28, 29.

Next, the polysilicon gate electrodes 28, 29 are fully silicided by thermal treatment to form the full-silicide gate electrodes 26, 27.

After removal of the non-reactive metal film 8, the interlayer insulating film 7 is deposited all over the surface of the semiconductor substrate 1 so that the semiconductor device shown in FIG. 15 can be obtained.

### C. Effect

The method for manufacturing the semiconductor device according to present the fourth embodiment includes a step of etching the side wall 20 such that the top end of the polysilicon gate electrode 29 is higher than the top end of the side wall 20.

Therefore, the silicide reaction can be promoted in the two-dimensional or three-dimensional manner. This can result in acceleration of supply of the metal atoms, thereby to facilitate formation of a metal-rich composition.

The semiconductor device according to the fourth embodiment includes the N-type MISFET with its top end formed so as to be lower that the top end of the side wall 20, and the P-type MISFET with its top end formed so as to be higher than the top end of the side wall 20.

Therefore, after the top end of the polysilicon gate electrode 28 is formed so as to be lower than the top end of the side wall 20 and the top end of the polysilicon gate electrode 29 is formed so as to be higher than the top end of the side wall 20, the electrodes can be silicided.

The suicide reaction proceeds in the one-dimensional manner on the N-type MISFET side, whereas the silicide reaction proceeds at an accelerated pace in the two-dimensional or three-dimensional manner on the P-type MISFET side.

For this reason, it is possible to make the metal composition ratio of the full-silicide gate electrode 27 in the P-type MISFET large as compared with that of the full-silicide gate electrode 26 in the N-type MISFET.

As a result, the metal gate CMOS structure having two kinds of work functions, the so-called dual work function metal gate CMOS structure can be realized with ease.

Further, as described in the first and second embodiments, by equalizing the top ends of the full-silicide gate electrodes 26 among a plurality of N-type MISFETs, the metal composition ratios can be equalized irrespective of the gate lengths. Further, by equalizing the top ends of the full-silicide gate electrodes 27 among a plurality of P-type MISFETs, the metal composition ratios can be equalized irrespective of the gate lengths.

The present invention is utilized for LSIs, mainly SoC products, which apply a high-tech CMOS process having a metal gate electrode whose material is silicide metal.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising at least one MISFET which has:
a full-silicide gate electrode, formed on a semiconductor substrate via a gate insulating film, and fully silicided; and
side walls, each formed on the side surfaces of said gate insulating film and said full-silicide gate electrode,
wherein the top end of said full-silicide gate electrode is lower than the top end of said side wall.

2. The semiconductor device according to claim 1, wherein
said at least one MISFET has a P-type MISFET and an N-type MISFET, and
the top end of said full-silicide gate electrode in said P-type MISFET is lower than the top end of said full-silicide gate electrode in said N-type MISFET.

3. The semiconductor device according to claim 1, wherein said at least one MISFET has a plurality of MISFETs with different gate lengths.

4. The semiconductor device according to claim 3, wherein said plurality of MISFETs are identical conductive-types.

5. A semiconductor device, comprising at least one MISFET which has:
a full-silicide gate electrode, formed on a semiconductor substrate via a gate insulating film, and fully silicided; and
side walls, each formed on the side surface of said full-silicide gate electrode,
wherein said at least one MISFET has:
a first MISFET in which the top end of said full-silicide gate electrode is formed so as to be lower than the top end of said side wall; and
a second MISFET in which the top end of said full-silicide gate electrode is formed so as to be higher the top end of said side wall.

6. The semiconductor device according to claim 5, wherein said first MISFET includes an N-type MISFET, and said second MISFET includes a P-type MISFET.

7. A method for manufacturing a semiconductor device, which comprises the steps of:
(a) preparing a semiconductor substrate which comprises on its main surface a structure having a polysilicon gate electrode formed via a gate insulating film, and side walls each formed on the side surfaces of said gate insulating film and the polysilicon gate electrode;
(b) adjusting the height of the top end of said polysilicon gate electrode by etching;
(c) forming a metal film so as to cover said polysilicon gate electrode subsequently to said process (b); and
(d) making a silicide reaction between said metal film and said polysilicon gate electrode by thermal treatment to fully silicide said polysilicon gate electrode for formation of a full-silicide gate electrode, and which forms at least one MISFET having said side walls each formed on side surfaces of said gate insulating film and said full-silicide gate electrode,
wherein said step (b) includes a step of adjusting the top end of said full-silicide gate electrode so as to be lower than the top end of said side wall.

8. The method for manufacturing a semiconductor device according to claim 7, wherein
said at least one MISFET has a P-type MISFET and an N-type MISFET, and
said step (b) includes a step of adjusting the top end of said polysilicon gate electrode in said P-type MISFET so as to be lower than the top end of said polysilicon gate electrode in said N-type MISFET.

9. The method for manufacturing a semiconductor device according to claim 7, wherein said step (a) includes a step of preparing the semiconductor substrate comprising a plurality of structures with different gate lengths.

10. The method for manufacturing a semiconductor device according to claim 7, further comprising a step of etching said side walls such that the top end of said polysilicon gate electrode is higher than the top end of said side wall, prior to said step (c).
